(19) United States
(12) Patent Application Publication
(10) Pub. No.: US 2014/0218872 A1
(43) Pub. Date: Aug. 7, 2014

(54) ELECTRONIC CIRCUIT AND METHOD OF FABRICATING THE SAME

(71) Applicant: Electronics and Telecommunications Research Institute, Daejeon (KR)

(72) Inventors: Chan Woo PARK, Daejeon (KR); Jae Bon KOO, Daejeon (KR); Soon-Won JUNG, Daejeon (KR); Bock Soon NA, Daejeon (KR); Sang Chul LIM, Daejeon (KR); Ji-Young OH, Daejeon (KR); Hye Yong CHU, Daejeon (KR)

(73) Assignee: Electronics and Telecommunications Research Institute, Daejeon (KR)

(21) Appl. No.: 14/089,378

(22) Filed: Nov. 25, 2013

(30) Foreign Application Priority Data
Feb. 6, 2013 (KR) 10-2013-0013442

(51) Int. Cl. H05K 1/02; H05K 3/00

(52) U.S. Cl. CPC H05K 1/0283; H05K 3/00
USPC 361/749; 361/760; 216/13; 264/104

(57) ABSTRACT

Provided is an electronic circuit. The electronic circuit includes: a substrate including a device region and a wiring region; an electronic device disposed on the device region; and a conductive wire disposed on the wiring region and connected to the electronic device, wherein the substrate has a first side where the electronic device and the conductive wire contact and a second side facing the first side; the first side and the second side of the wiring region have a convex structure; the first side of the device region is flat; and the device region is thicker than the wiring region.

### CROSS-REFERENCE TO RELATED APPLICATIONS

This U.S. non-provisional patent application claims priority under 35 U.S.C. §119 of Korean Patent Application No. 10-2013-0013442, filed on Feb. 6, 2013, the entire contents of which are hereby incorporated by reference.

### BACKGROUND OF THE INVENTION

The present invention disclosed herein relates to an electronic circuit and a method of fabricating the same, and more particularly, to a stretchable electronic device and a method of fabricating the same.

Recently, with the development of multimedia, the importance of a stretchable electronic circuit is increasing. The stretchable electronic device may be applied to various applications such as a sensor skin for robot, a wearable communication device, a human body built-in/attachable bio device, and/or a next generation display. Accordingly, an organic light emitting display (OLED), a liquid crystal display (LCD), an electrophoretic display (EPD), a plasma display panel (PDP), a thin-film transistor (TFT), a microprocessor, and random access memory (RAM) are required to be fabricated on a stretchable substrate. The stretchable substrate needs to maintain an electrical function even when it expands or contracts.

### SUMMARY OF THE INVENTION

The present invention provides a stretchable electronic circuit absorbing impact applied from outside and maintaining a circuit function.

Embodiments of the present invention provide electronic circuits including: a substrate including a device region and a wiring region; an electronic device disposed on the device region; and a conductive wire disposed on the wiring region and connected to the electronic device, wherein the substrate has a first side where the electronic device and the conductive wire contact and a second side facing the first side; the first side and the second side of the wiring region have a convex structure; the first side of the device region is flat; and the device region is thicker than the wiring region.

In some embodiments, an uppermost part of the wiring region may have a lower level than an uppermost part of the device region.

In other embodiments, the wiring region may be more flexible than the device region.

In still other embodiments, the convex structure may be rounded.

In even other embodiments, the convex structure may have a waveform in which waves progress in one direction, a waveform in which waves progress in one direction and another direction perpendicular to the one direction, a waveform in which waves progress in a zigzag direction, or a waveform in which waves progress in an irregular direction.

In yet other embodiments, the conductive wire may extend along the convex structure and may have a curve of a waveform.

In further embodiments, the electronic circuits may further include a first capping layer disposed on the first side and configured to cover the electronic device and the conductive wire.

In still further embodiments, the electronic circuit may further include a second capping layer spaced from the electronic device and the conductive wire on the second side.

In even further embodiments, the device region may have a thickness of about 10 μm to about 100 μm, and the wiring region may have a thickness of about 1 μm to about 10 μm.

In other embodiments of the present invention, provided are methods of fabricating an electronic circuit. The method include: providing a mold having a rounded pattern; forming a substrate covering the mold; forming a flat device region on the substrate by removing a portion of the substrate; forming a wiring region having a convex structure on the substrate; and forming a conductive wire on the wiring region and forming electronic devices on the device region, wherein the wiring region has a thinner thickness than the device region and has the convex structure extending along a pattern of the mold.

In some embodiments, the forming of the wiring region may include spin-coating polymer to allow an uppermost surface of the wiring region to have a lower level than an uppermost surface of the device region.

In other embodiments, the forming of the device region may include etching the substrate corresponding to the wiring region.

In still other embodiments, the providing of the molding may include:

providing a mother substrate having an angular recess; and forming a sacrificial layer having a rounded surface on the mother substrate.

In even other embodiments, the providing of the mold may include: forming a photoresist layer on a mother substrate; forming an angular pattern on the photoresist layer; and forming the rounded pattern by reflowing the photoresist layer, wherein the rounded pattern may have a form corresponding to the convex structure.

In yet other embodiments, the providing of the mold may include: providing a mother substrate coated with a photoresist layer; and forming a rounded pattern on the photoresist layer by using a grayscale photomask, wherein the rounded pattern may have a waveform corresponding to the convex structure.

In further embodiments, the methods may further include a first capping layer covering the conductive wire and the electronic device on the substrate, wherein the first capping layer may include an elastomer.

In still further embodiments, the methods may further include a second capping layer spaced from and facing the conductive wire and the electronic device, wherein the second capping layer may include an elastomer.

In even further embodiments, the methods may further include separating the substrate from the mold.

In yet further embodiments, the electronic devices may be spaced from each other, and the conductive wire may extend along the convex structure and electrically connect the electronic devices.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a plan view illustrating an electronic circuit according to an embodiment of the present invention;

FIG. 2 is a sectional view taken along a line A-B of FIG. 1;

FIGS. 3A to 3D are perspective view illustrating a convex structure according to embodiments of the present invention;

FIGS. 4 and 5 are sectional views illustrating a method of fabricating a mold according to an embodiment of the present invention;

FIGS. 6 and 7 are sectional views illustrating a method of fabricating a mold according to another embodiment of the present invention;

FIGS. 8 and 9 are sectional views illustrating a method of fabricating a mold according to another embodiment of the present invention; and

FIGS. 10 to 16 are sectional views illustrating a method of fabricating an electronic circuit according to an embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

The meaning of “include,” “comprise,” “including,” or “comprising,” specifies a property, a region, a fixed number, a step, a process, an element and/or a component but does not exclude other properties, regions, fixed numbers, steps, processes, elements and/or components.

In the drawings, the dimensions of layers and regions are exaggerated for clarity of illustration. It will also be understood that when a layer (or film) is referred to as being ‘on’ another layer or substrate, it can be directly on the other layer or substrate, or intervening layers may also be present. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present. Like reference numerals refer to like elements throughout.

The meaning of “include,” “comprise,” “including,” or “comprising,” specifies a property, a region, a fixed number, a step, a process, an element and/or a component but does not exclude other properties, regions, fixed numbers, steps, processes, elements and/or components. Hereinafter, it will be described about an exemplary embodiment of the present invention in conjunction with the accompanying drawings.

Unless otherwise defined therein, terms used in this specification are interpreted by those skilled in the art as typically known meanings.

Hereinafter, an electronic circuit according to an embodiment of the present invention is described with reference to the accompanying drawings.

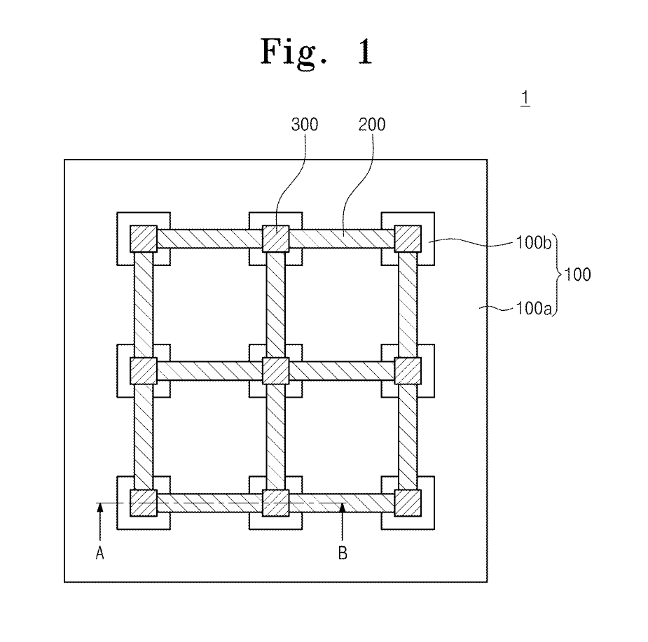

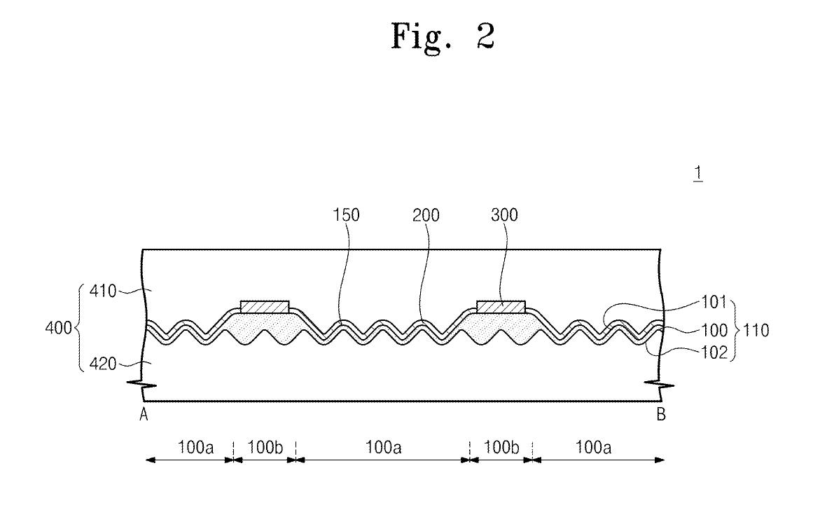

FIG. 1 is a plan view illustrating an electronic circuit according to an embodiment of the present invention. FIG. 2 is a sectional view taken along a line A-B of FIG. 1.

Referring to FIGS. 1 and 2, the electronic circuit 1 includes a conductive wire 200, an electronic device 300, and a capping layer 400, on a substrate 100.

The substrate 100 may include elastomeric material. For example, the substrate 100 may include polyimide. The substrate 100 includes a wiring region 100a and a device region 100b. The device region 100b may be flat. The device region 100b has a thickness of about 10 μm to about 100 μm and may be more rigid than the wiring region 100a. A convex structure 150 may be provided on the wiring region 100a. The convex structure 150 may be rounded. For example, the convex structure 150 may have a waveform. The uppermost surface of the convex structure 150 may have a lower level than that of the device region 100b. The wiring region 100a may have a thinner thickness than the device region 100b, for example, a thickness of about 1 μm to about 10 μm. As the wiring region 100a has a thinner thickness than the device region 100b and the convex structure 150, it may be more flexible than the device region 100b.

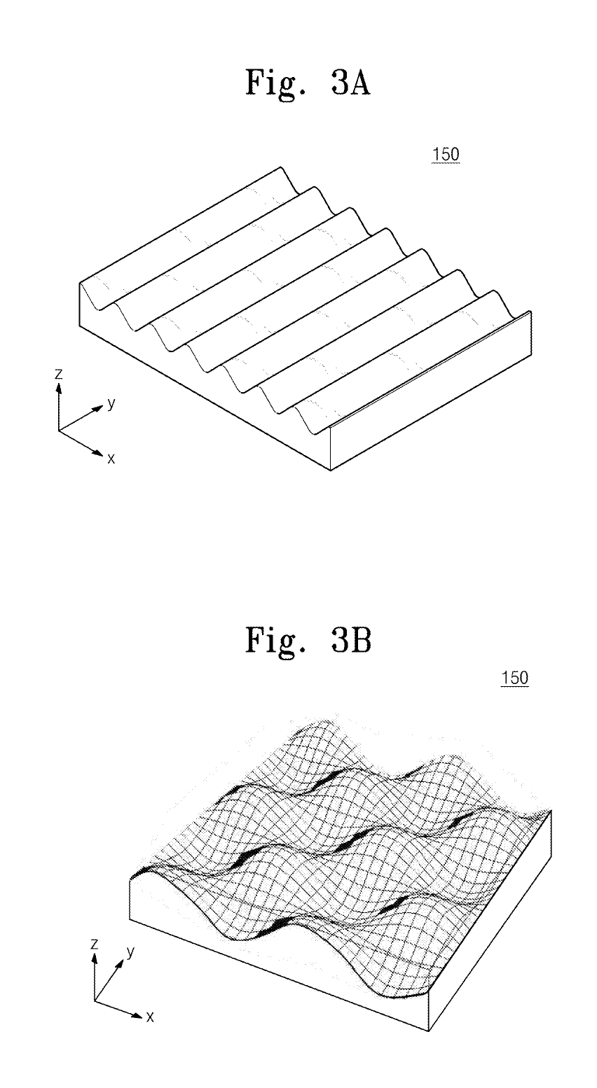

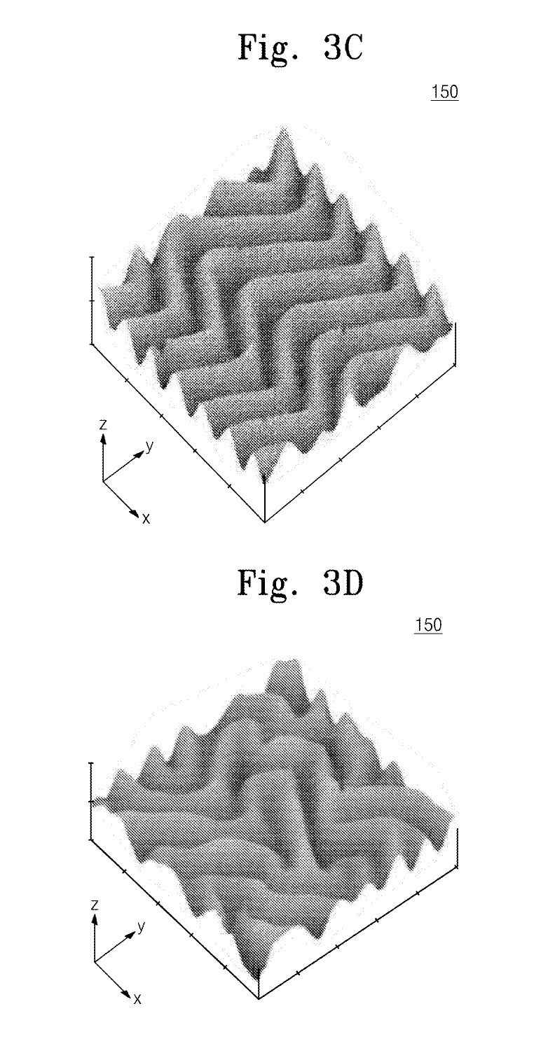

FIGS. 3A to 3D are perspective view illustrating a convex structure according to embodiments of the present invention. Hereinafter, this will be described with reference to FIGS. 1 and 2.

Referring to FIG. 3A, the convex structure 150 may have a waveform in which waves progress in an x-axis direction. For example, an x-axis section of the convex structure 150 is curved and a y-axis section and plane of the convex structure 150 may have a straight line form. A z-axis of the convex structure 150 may have different heights.

Referring to FIG. 3B, the convex structure 150 may have a waveform in which waves progress in an x-axis and a y-axis. For example, x-axis and y-axis sections of the convex structure 150 may be curved. The convex structure 150 may have different heights in a z-axis. The z-axis of the convex structure 150 may have different heights.

Referring to FIG. 3C, the convex structure 150 may have a waveform in which waves progress in a zigzag direction. For example, an x-axis section, a y-axis section, and a plane (i.e., a z-axis section) of the convex structure 150 may be curved. The z-axis of the convex structure 150 may have different heights.

Referring to FIG. 3D, the convex structure 150 may have a waveform in which waves progress in an irregular direction. An x-axis section, a y-axis section, and/or a plane of the convex structure 150 may be curved in an irregular form. The z-axis of the convex structure 150 may have different heights.

Referring to FIGS. 1 and 2 again, the conductive wire 200 may be provided on the wiring region of the substrate 100. The conductive wire 200 may have a pattern on the substrate 100. The conductive wire 200 may have a plane including straight lines extending in one direction. The conductive wire 200 may further include straight lines extending in a different direction than the one direction. The conductive line 200 may extend on a portion of the device region 100b. The conductive wire 200 may extend along the convex structure 150 of the substrate 100 and may be curved. For example, the conductive wire 200 may have the same waveform as that of FIGS. 3A to 3D. The conductive wire 200 may contact the electronic device 300. The conductive wire may be disposed between the electronic devices 300 to electrically connect the electronic devices 300. The conductive wire 200 may include conductive material. For example, the conductive wire 200 may include at least one of aluminum, gold, copper, tungsten, polysilicon doped with an impurity and/or alloys thereof.

The electronic device 300 may be provided on the device region 100b of the substrate 100. The electronic device 300 may include at least one of an organic light emitting display (OLED), a liquid crystal display (LCD), an electrophoretic display (EPD), a plasma display panel (PDP), a thin-film transistor (TFT), a microprocessor, and/or random access memory (RAM).

The capping layer 400 may include a first capping layer 410 and a second capping layer 420. The first capping layer 410 may be provided on a first side 101 of the substrate 100. The first capping layer 410 may cover the conductive wire 200 and/or the electronic device 300. The capping layer 420 may be provided on a second side 102 of the substrate 100. The second capping layer 420 may be spaced from the conductive wire 200 and the electronic device 300. The capping layer 400 may include elastomeric material, for example, polydimethylsiloxane (PDMS). The capping layer 400 may protect the conductive wire 200 and/or the electronic device 300. As another example, the first capping layer 410 and/or the second capping layer 420 may be omitted.

The electronic circuit 1 may be a stretchable electronic circuit. External impact may be applied to the electronic circuit 1. Since the convex structure 150 and/or the conductive wire 200 of the substrate 100 have/has a curvature of a waveform, the impact may be absorbed. The impact applied to the electronic circuit 1 may be distributed through the capping layer 400 in addition to the substrate 100. In spite of the external impact, the conductive wire 200 may maintain an electrical connection between the electronic devices 300. As the electronic device 300 is disposed on the flat device region 100b, it may not be affected from external impact. Therefore, functions of the electronic circuit 1 may be maintained.

A method of fabricating an electronic circuit according to embodiments of the present invention is described. Hereinafter, for conciseness of description, redundant content for the description of FIGS. 1 to 3 is omitted.

### EXAMPLE 1

### Of Fabricating Mold

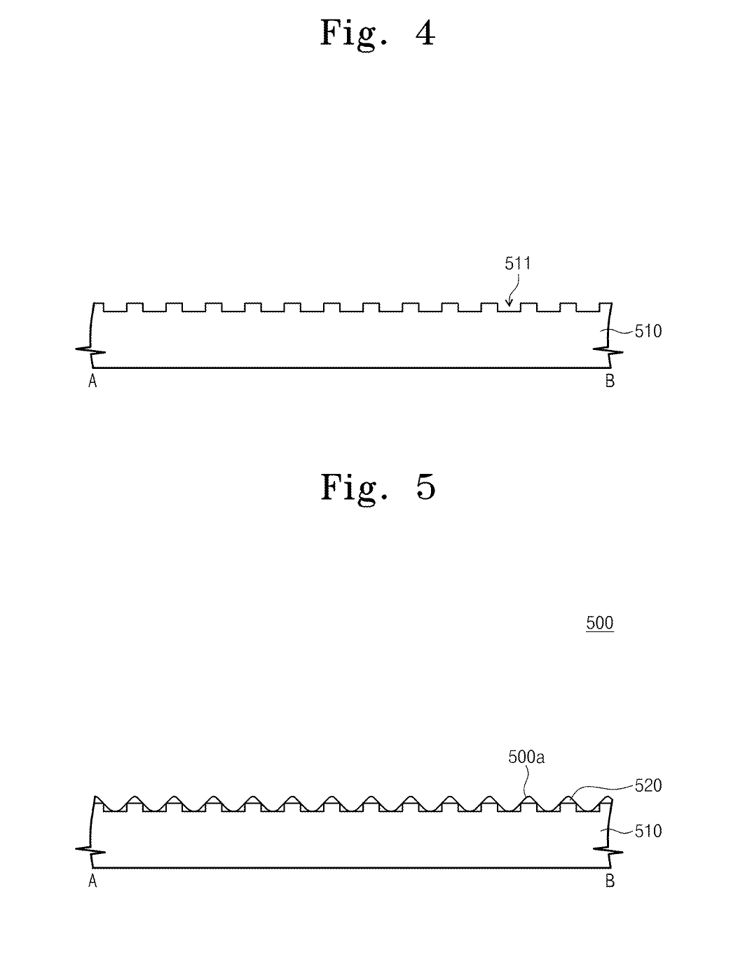

FIGS. 4 and 5 are sectional views illustrating a method of fabricating a mold according to an embodiment of the present invention.

Referring to FIG. 4, a mother substrate 510 having an angular recess 511 is provided. The mother substrate 510 may be hard. For example, the mother substrate 510 may be a silicon wafer. As another example, the mother substrate 510 may include at least one of glass, plastic, indium tin oxide (ITO), and/or fluoride containing tin oxide (FTO). The recess 511 may be formed by patterning the mother substrate 510. The top surface of the recess 511 may have a lower level than that of the mother substrate 510.

Referring to FIG. 5, a sacrificial layer 520 may be formed on the mother substrate 510. For example, the sacrificial layer 520 may be formed by spin-coating polymethylmethacrylate (PMMA) on the mother substrate 510. The sacrificial layer 520 may cover the recess 511 of the mother substrate 510 to form a rounded pattern 500a. The rounded pattern 500a may be formed to have a form corresponding to the convex structure 150 of the substrate 100 of FIG. 1. For example, the rounded pattern 500a may have a waveform such as that shown in FIGS. 3A to 3D. Through the fabricating method according to the above-mentioned embodiment of the present invention, the mold 500 having the rounded pattern 500a may be completed.

### EXAMPLE 2

### Of Fabricating Mold

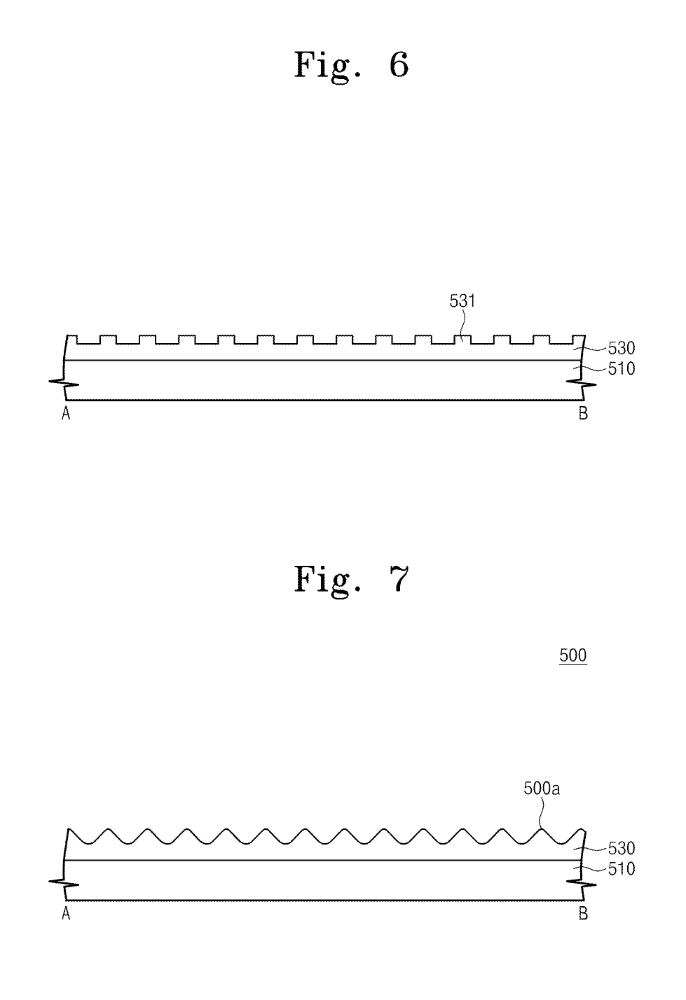

FIGS. 6 and 7 are sectional views illustrating a method of fabricating a mold according to another embodiment of the present invention. As mentioned above, redundant description is omitted.

Referring to FIG. 6, a mother substrate 510 including a photoresist layer 530 is provided. The mother substrate 510 may include silicon, glass, plastic, ITO, or FTO. The photoresist layer 530 may have an angular pattern 531. The photoresist layer 530 may be formed on the mother substrate 510 through patterning including deposition and exposure processes of photoresist material.

Referring to FIG. 7, a rounded pattern 500a may be formed on the photoresist layer 530. Through a reflow process, the angular pattern 531 of FIG. 5 may change into the angular pattern 500a. The reflow process may be performed at more than a glass transition temperature of the photoresist layer 530. The rounded pattern 500a may have a waveform such as that shown in FIGS. 3A to 3D. Through the fabricating method according to the above-mentioned embodiment of the present invention, a mold 500 having the rounded pattern 500a may be completed.

### EXAMPLE 3

### Of Fabricating Mold

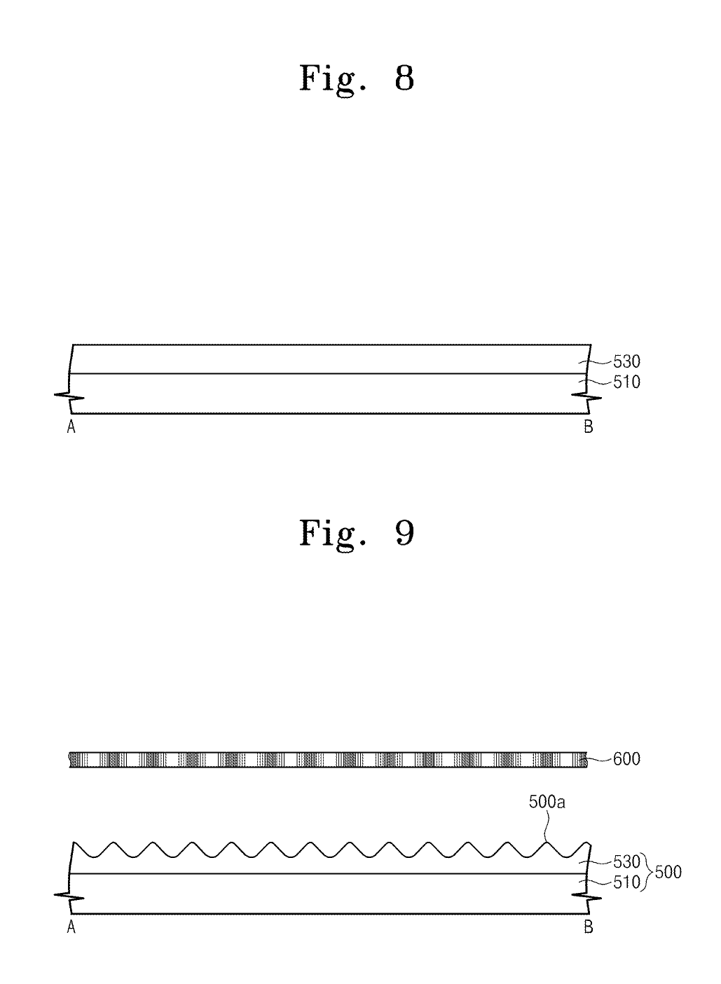

FIGS. 8 and 9 are sectional views illustrating a method of fabricating a mold according to another embodiment of the present invention. As mentioned above, redundant description is omitted.

Referring to FIG. 8, a mother substrate 510 including a photoresist layer 530 is provided. Each of the mother substrate 510 and the photoresist layer 530 may include the same or similar materials as described in FIG. 6.

Referring to FIG. 9, a rounded pattern 500a may be formed on the photoresist layer 530. The rounded pattern 500a may have a waveform such as that shown in FIGS. 3A to 3D. Patterning is performed through a gray scale exposure process (lithography) using a grayscale photomask 600 capable of adjusting the amount of penetrating light. As light penetrates the grayscale photomask 600, the degree of exposure of the photoresist layer 530 may vary according to the amount of penetrating light. The photoresist layer 530 may be exposed as periodically changing a progression direction of light, a transmittance of light, and/or the intensity of light. Accordingly, by adjusting the photoresist layer 530 removed during development, a form of the pattern 500a may be controlled. For example, a waveform may be formed by adjusting amplitude, period, and orientation.

Through the fabricating method according to the above-mentioned embodiment of the present invention, a mold 500 having the rounded pattern 500a may be completed.

### EXAMPLE OF FABRICATING ELECTRONIC CIRCUIT

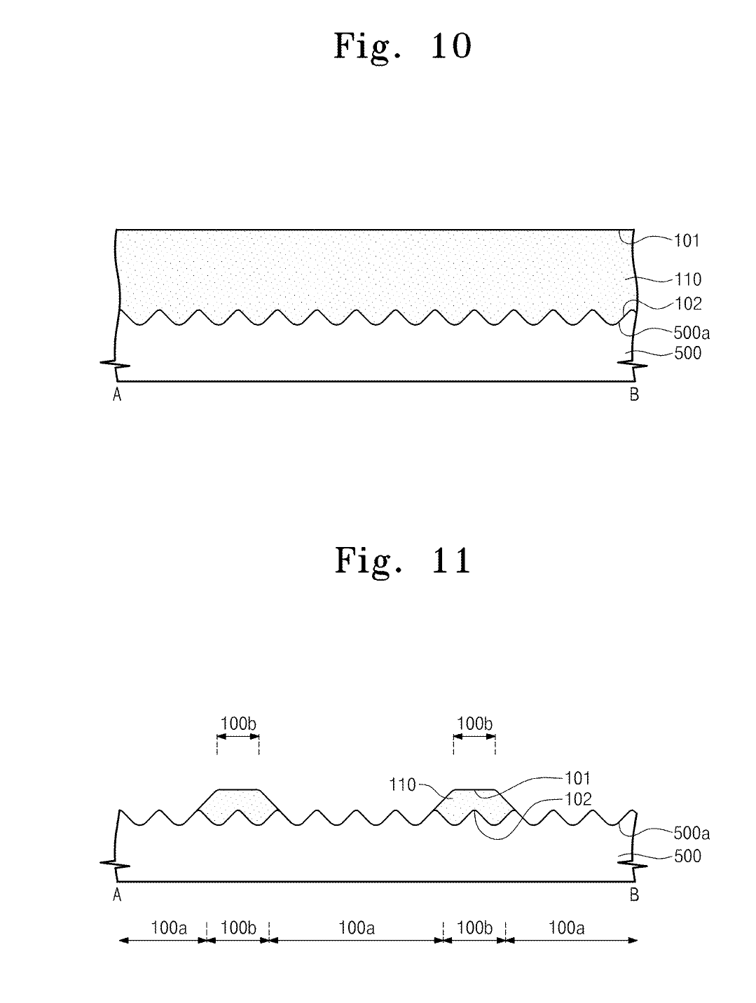

FIGS. 10 to 16 are sectional views illustrating a method of fabricating an electronic circuit according to an embodiment of the present invention. As mentioned above, redundant description is omitted.

Referring to FIG. 10, a substrate 110 may be formed on a mold 500. The mold 500 may be the one 500 having the rounded pattern 500a fabricated as an example of FIGS. 6 and 7 or an example of FIGS. 8 and 9. For example, the substrate 110 may cover the mold 500 by spin-coating flexible polymer such as polyimide on the mold 500. The substrate 110 may have a second side 102 contacting the mold 500 and a first side 101 facing the second side 102. The substrate 110 may be formed to have the flat first side 101 by adjusting the thickness of the substrate 110.

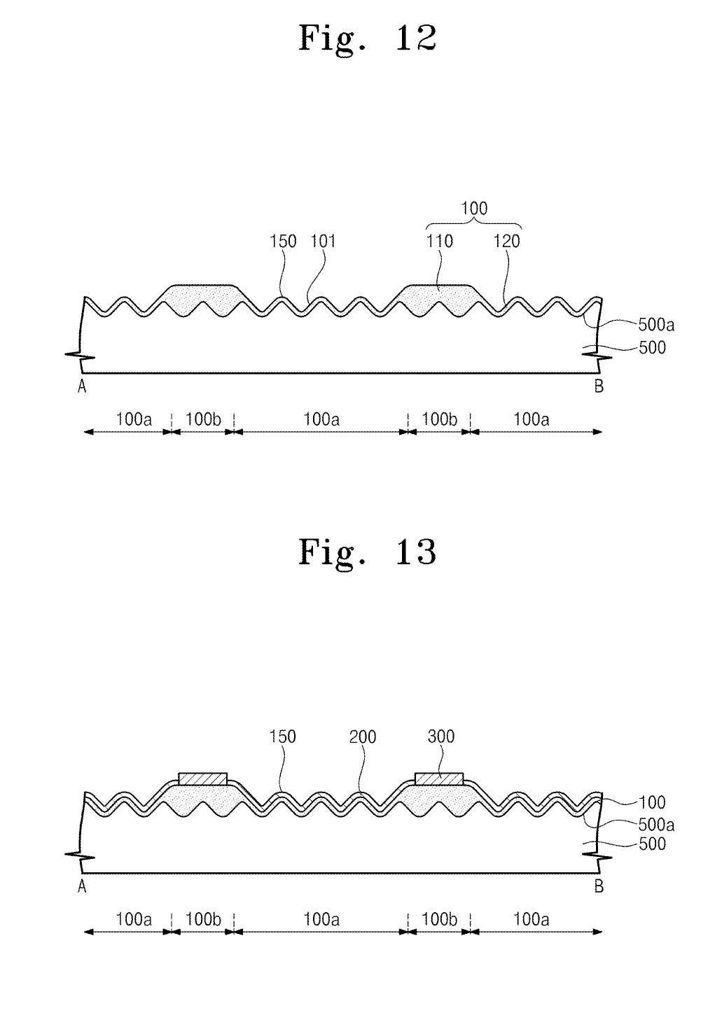

Referring to FIG. 11, a portion of the substrate 110 may be removed thereby forming a device region 100b. For example, the removal of the substrate 110 may be performed through wet etching. That is, the substrate 110 corresponding to the wiring region 100a may be removed. The substrate corresponding to the device region 100b may not be removed. The first side 101 of the device region 100b may be flat.

Referring to FIG. 12, a substrate 120 corresponding to the wiring region 100a may be formed by spin-coating polymer such as polyimide on the mold 500. The wiring region 100a may be formed to have a thickness of about 1 μm to about 10 μm. A convex structure 150 may be formed on a first side 101 in the wiring region 100a. The convex structure 150 may extend along the pattern 500a of the mold 500 and may be rounded. The convex structure 150 may have a form corresponding to the pattern 500a of the mold 500. The uppermost surface of the wiring region 100a may have a lower level than that of the device region 100b.

Referring to FIG. 13, the conductive wire 200 may be formed on the wiring region 100a of the substrate 100. The conductive wire 200 may be formed on a portion of the device region 100b. An electronic device 300 may be formed on the device region 100b of the substrate 100. A formation process of the electronic device 300 may be performed before the conductive wire 200 is formed.

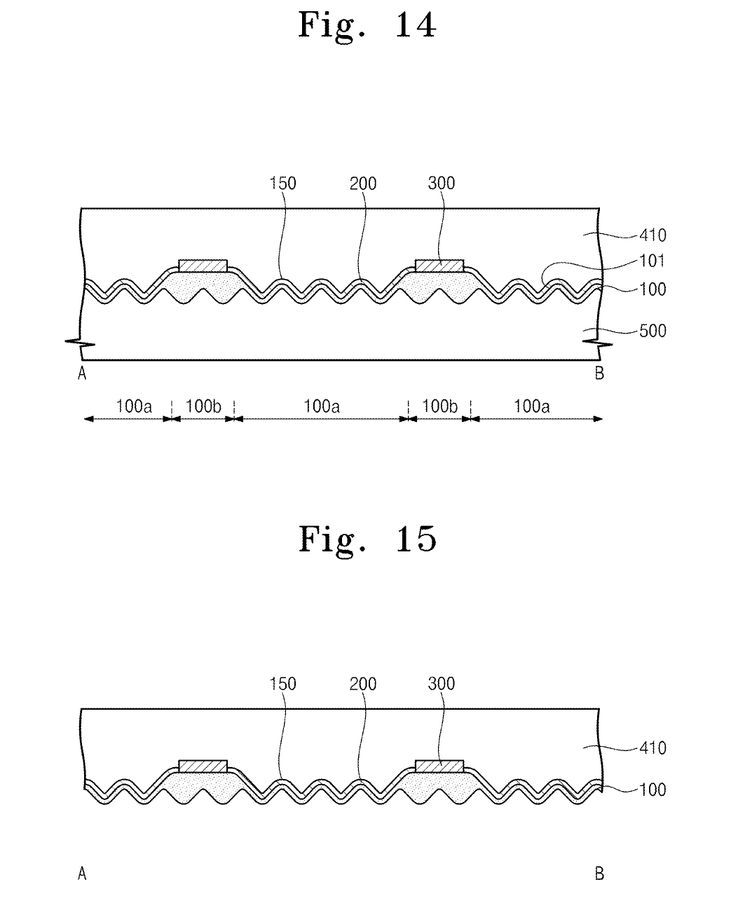

Referring to FIG. 14, a first capping layer 410 is formed on the first side 101 of the substrate 100 so as to cover the conductive wire 200 and the electronic device 300. The first capping layer 410 may be formed by coating and solidifying elastomeric material, for example, PDMS.

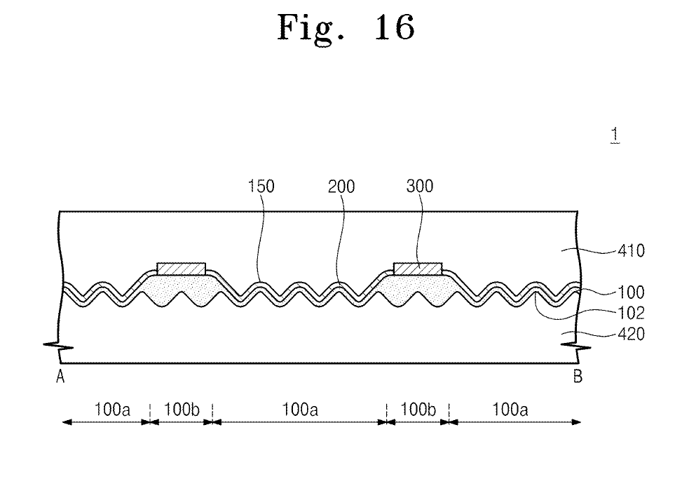

Referring to FIG. 15, the mold 500 is removed so that the substrate 100 may be separated from the mold 500. The removal of the mold 500 may be performed through a lift off process or mechanical separation.

Referring to FIG. 16, a second capping layer 420 may be formed to cover a second side 102. The second capping layer 420 may be formed by coating and solidifying elastomeric material, for example, PDMS. Therefore, the electronic device 1 may be fabricated completely. As another example, the formation of the second capping layer 420 may be omitted.

Patterning by a pre-strain method may be difficult to adjust a position at which a pattern is formed, an area of the pattern, and a shape of the pattern. A method of fabricating the electronic circuit 1 according to an embodiment of the present invention may easily adjust the areas and positions of the wiring region 100a and the device region 100b. The convex structure 150 may be fabricated to have a desired structure and/or form. For example, the convex structure 150 having a waveform may be fabricated by adjusting an amplitude, period, and/or orientation of a wave. Additionally, the stretchable electronic circuit 1 may be fabricated using polymer such as polyimide instead of elastomeric material.

According to an embodiment of the present invention, an electronic device may include a substrate having a device region and a wiring region. The device region is flat and the wiring region has a rounded convex structure. The thickness of the wiring region is thinner than that of the device region. The wiring region may be more flexible than the device region. According to the concept of the present invention, an electronic device may be flexible and stretchable. An impact applied from the outside to the electronic device may be received by a wiring region and a conductive wire. That is, the electronic device may not be affected by external impact. Therefore, an electronic circuit may maintain its functions.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An electronic circuit comprising:
a substrate including a device region and a wiring region;
an electronic device disposed on the device region; and
a conductive wire disposed on the wiring region and connected to the electronic device,
wherein
the substrate has a first side where the electronic device and the conductive wire contact and a second side facing the first side;
the first side and the second side of the wiring region have a convex structure;
the first side of the device region is flat; and
the device region is thicker than the wiring region.

2. The electronic circuit of claim 1, wherein an uppermost part of the wiring region has a lower level than an uppermost part of the device region.

3. The electronic circuit of claim 1, wherein the wiring region is more flexible than the device region.

4. The electronic circuit of claim 1, wherein the convex structure is rounded.

5. The electronic circuit of claim 1, wherein the convex structure has a waveform in which waves progress in one direction, a waveform in which waves progress in one direction and another direction perpendicular to the one direction, a waveform in which waves progress in a zigzag direction, or a waveform in which waves progress in an irregular direction.

6. The electronic circuit of claim 1, wherein the conductive wire extends along the convex structure and has a curve of a waveform.

7. The electronic circuit of claim 1, further comprising a first capping layer disposed on the first side and configured to cover the electronic device and the conductive wire.

8. The electronic circuit of claim 1, further comprising a second capping layer spaced from the electronic device and the conductive wire on the second side.

9. The electronic circuit of claim 1, wherein the device region has a thickness of about 10 μm to about 100 μm, and the wiring region has a thickness of about 1 μm to about 10 μm.

10. A method of fabricating an electronic circuit, the method comprising:
providing a mold having a rounded pattern;
forming a substrate covering the mold;
forming a flat device region on the substrate by removing a portion of the substrate;
forming a wiring region having a convex structure on the substrate; and
forming a conductive wire on the wiring region and forming electronic devices on the device region,
wherein the wiring region has a thinner thickness than the device region and has the convex structure extending along a pattern of the mold.

11. The method of claim 10, wherein the forming of the wiring region comprises spin-coating polymer to allow an uppermost surface of the wiring region to have a lower level than an uppermost surface of the device region.

12. The method of claim 10, wherein the forming of the device region comprises etching the substrate corresponding to the wiring region.

13. The method of claim 10, wherein the providing of the molding comprises:
providing a mother substrate having an angular recess; and
forming a sacrificial layer having a rounded surface on the mother substrate.

14. The method of claim 10, wherein the providing of the mold comprises:
forming a photoresist layer on a mother substrate;
forming an angular pattern on the photoresist layer; and
forming the rounded pattern by reflowing the photoresist layer,
wherein the rounded pattern has a form corresponding to the convex structure.

15. The method of claim 10, wherein the providing of the mold comprises:
providing a mother substrate coated with a photoresist layer; and
forming a rounded pattern on the photoresist layer by using a grayscale photomask,
wherein the rounded pattern has a waveform corresponding to the convex structure.

16. The method of claim 10, further comprising a first capping layer covering the conductive wire and the electronic device on the substrate, wherein the first capping layer comprises an elastomer.

17. The method of claim 10, further comprising a second capping layer spaced from and facing the conductive wire and the electronic device, wherein the second capping layer comprises an elastomer.

18. The method of claim 10, further comprising separating the substrate from the mold.

19. The method of claim 10, wherein the electronic devices are spaced from each other, and the conductive wire extends along the convex structure and electrically connect the electronic devices.
